(19) United States
(12) Patent Application Publication
(10) Pub. No.: US 2011/0000543 A1
(43) Pub. Date: Jan. 6, 2011

(54) SOLAR ENERGY COLLECTION AND CONVERSION SYSTEM

(76) Inventor: Joseph P. Errico, Green Brook, NJ (US)

Correspondence Address: SNR DENTON US LLP, P.O. BOX 061080, CHICAGO, IL, 60606-1080, US

(21) Appl. No.: 12/828,757

(22) Filed: Jul. 1, 2010

Related U.S. Application Data
(60) Provisional application No. 61/222,844, filed on Jul. 2, 2009.

(51) Int. Cl. H01L 31/04; F24J 2/38

(52) U.S. Cl. 136/259; 126/573

(57) ABSTRACT

A solar energy collection and conversion system includes at least one mirror array, with each array including a multiplicity of mirrors, and each array of mirrors reflecting incident sunlight onto a common target. The common target serves as a collection point where the reflected sunlight energy converges and is thereby concentrated. The target comprises an energy to electricity conversion device, for example, a photovoltaic device, and/or a reservoir of material which can be heated by the incident light energy such that the energy may be subsequently extracted to generate electricity.

### CROSS-REFERENCE TO RELATED APPLICATIONS

The present application claims the benefit of U.S. Provisional Application No. 61/222,844 filed 2 Jul. 2009; which is incorporated herein by reference in its entirety.

### FIELD

The present application relates generally to a system for capturing useful solar energy having at least one collection array for collecting incident solar energy, at least one concentrating means by which the collected solar energy is focused, and an energy transfer and redirection system by which the concentrated solar energy is delivered to a desired location.

### BACKGROUND

While there exists a wide variety of techniques for generating electricity, the vast majority of the electric power used in the modern world is generated by power plants that convert heat from fuel into steam, and use steam to turn a generator turbine. These power plants typically either burn petroleum products, such as coal, natural gas, and oil to generate heat, or they utilize the heat associated with the controlled chain reaction of uranium and/or plutonium to heat water into steam. These power generation techniques are categorized as “non-renewable” inasmuch as the fuels that generate the heat to boil water to steam that is converted into electricity are collected from terrestrial sources that are finite.

To the extent that water and wind are constantly moving through cycles driven by solar and geothermal energy, these sources of electricity are considered “renewable”. Examples of renewable energy generation include hydroelectric plants and wind turbines. These examples convert the potential and kinetic mechanical energy of water and wind, respectively, into electricity, and do not require the heating of any medium (such as steam) to drive a generator turbine.

The processes for converting heat into electricity is not completely efficient, and because waste heat is almost always generated during the conversion processes, an interesting and important relationship exists between the generation of electricity by traditional fossil fuel and nuclear power plants and the use of freshwater. In fact, large quantities of fresh water resources are typically used during power plant operations. As the demand for electric power increases and the availability of freshwater for other purposes (such as consumption, agriculture, and other industrial uses) decreases, a fundamental tension arises between the demand for electricity and the demand for water. A shortage of freshwater is now recognized to be a major impediment to the continued industrialization of the world. Further confounding the situation is the fact that most techniques for desalinating water require the use of electricity; thus the basis of this challenge becomes obvious. Unless techniques for generating power that do not consume freshwater are identified and made economically viable, or a techniques for generating large quantities of freshwater are discovered, economic pressures on both sides of the water/energy equation will continue to rise.

One of the most promising techniques for generating electricity that uses minimal water resources is solar power. Collecting solar energy fall into four categories: photovoltaics, concentrators, towers, and water heaters. Solar photovoltaics, or solar cells, are semiconductor panels that respond to light, or heat generated by the light, by creating a voltage. Traditional solar photovoltaics (hereinafter “PV”) have typically been designed to respond most efficiently at energy concentrations at or close to that of incident solar radiation at the Earth's surface, i.e., approximately 1 kilowatt per square meter. Efficiencies of radiation to electricity conversion for PV devices have typically ranged from 15-25%, with most commercially available PVs operating in the 17-22% efficiency range. Higher efficiencies can be achieved with high efficiency PV cells. An alternative to PV is thermophotovoltaics (hereinafter “TPV”), which converts heat from light into electricity. Additionally, concentrator solar photovoltaics (hereinafter “CPVs”) are designed to operate at higher efficiencies (i.e., close to 40% and above) than PV or TPV devices. These CPVs, however, require that the incident sunlight be focused onto the surface of the device with a concentration factor approaching one thousand. That is, CPV devices function most efficiently when the light energy incident onto its surface is close to 1 megawatt per square meter.

Unfortunately, applications for CPV technology have been limited inasmuch as 40% conversion efficiencies necessarily mean that 60% of the energy incident on the device is waste energy; waste energy being defined as the amount or percentage of incident light energy that is not converted into electricity. Waste energy is either reflected away from the surface of the CPV, or it is absorbed and converted into heat. Limited reflectance is a design criteria for high efficiency CPVs, thus the majority of the waste energy is converted to heat. This heat energy can either be carried away from the CPV by thermal radiation emitted by the surface (re-emitted as infrared photons), or can be dissipated by thermal conduction directly through the air or the substrate of the CPV. At the low temperatures required for normal operation (under 150° Celsius), thermal radiation emission accounts for very little of the dissipation of waste energy. Typically, electronic devices that generate heat are cooled passively by means of attaching relatively larger sized thermal heat sink such as high surface area metal “fins” that dissipate heat to air, and, thus a steady state of absorbed heat to dissipated heat is reached. This solution works for PVs, with waste energies that are typically significantly less than 800 watts per square meter.

CPVs offer the potential to revolutionize the solar photovoltaic industry, and perhaps even the electric utility industry as a whole, offering electricity generation at cost savings over a large arrays of 25-250 times what PVs can offer. However, while CPVs have a lower waste energy percentage, the absolute magnitude of this waste energy is dramatically larger, on the order of 600 kilowatts per square meter. If only passive means were utilized to cool the CPVs, the temperature associated with this level of waste energy is well beyond the safe operating temperature of the CPVs (likely beyond the melting temperatures of the constituent materials). In order for CPVs to become widely used in utility applications, a safe and reliable means of actively cooling the cells must be provided.

In addition to CPVs, which concentrate incident light for direct energy conversion from light to electricity, another class of simpler solar concentrators utilize a series of mirrors to reflect sunlight onto a large structure holding a molten salt or metal. Typically, the mirrors are laid out in a series of concentric rings with a tower structure built at the center of the rings. The reflected solar energy is directed on the tower and heats a reservoir of molten salt or metal, through which water is passed to generate steam to drive a generator. Typically, geometry requires that the larger the array, the taller and more robust the tower structure must be, which in turn drives the cost of the overall system.

Slightly more elaborate solar concentrators use curved mirrors in the shape of parabolic troughs to concentrate light onto a focal line. A tube filled with oil is heated at the focal line, which oil is then used to heat water to produce low pressure steam for a generator. Low efficiencies and high initial costs (i.e., generators, buildings, high temperature fluid handling equipment, etc.) have traditionally limited the usage of this, and the other solar tower technologies for large scale energy production.

Another solar concentrator technology that has recently been deployed for commercial energy production in the Mohave Desert utilizes a field of individual generators, each comprised of dozens of large parabolic mirrors that concentrate sunlight onto the heat collection terminals of specially-designed Stirling engines. Each of the generators, and the corresponding mirrors are mounted to a pivoting structure that tracks the sun by means of large motors guided by a heliostat. While approaching cost effectiveness, this technology remains less efficient than would make it truly competitive with coal and natural gas power plants. If the technology does not make fiscal sense, i.e., be competitive with alternative fossil fuel energy options, the only way it will be implemented is if government subsidizes it by direct monetary grants, or by legislative acts requiring utilities to acquire a certain percentage of their electrical energy from non-fossil fuel based sources.

Solar water heaters are universally considered one of the most efficient uses of solar energy inasmuch as a large portion of household usage of electricity and/or natural gas is dedicated to heating water for bathing, cleaning, etc. A simple dark colored tank, positioned to receive sunlight during the day can provide ample hot water for most homes during a significant portion of the year. Unfortunately, water heating of this kind has not been scaleable to utility, or even regional applications.

### SUMMARY

One object of the present application is to provide a solar collector that includes less expensive mirrors to aim and/or direct solar rays at a target. In some embodiments, the reflector of these embodiments is comprised of an array of flat mirrors positioned to redirect sunlight incident on each mirror toward a common target. The mirrors can be set in any pattern, for example a pseudo-Fresnel pattern or a concentric pattern of rings. The mirrors are generally banked so that the light reflecting off the array of mirrors has a substantially common focal point. The flat mirrors can be mounted on a support structure that can move in relation to the sun such that the common target moves with the mirrors (such as at the focal point of a parabola). In certain other embodiments, it is desirable to have the support structure and the mirrors aligned in such a way that the common first target is stationary.

In certain embodiments, at least one lens, or a series of lenses, are positioned to produce a collimated beam of light that can be redirected off the array of mirrors toward the target. In such embodiments, a targeting mirror may be positioned in the path of the collimated beam to direct the solar energy at the target.

In other embodiments, a light pipe is positioned to direct the light reflected off the array of mirrors toward the target. In certain aspects of such an embodiment, the light pipe may have a different diameter at the proximal entrance than at the distal end, thus serving to alter the concentration of the light traveling along its extent.

In some aspects, the target may be a heat engine, a reservoir of water or molten salt, a high efficiency photovoltaic cell, concentrator photovoltaic cell, or other thermal energy storage or conversion device. The mirrors, while generally being flat, can be any shape and/or size. In other aspects, several of the above arrays may be joined to further concentrate the light.

Thus, in some embodiments, a solar collector is provided. The solar collector comprises: an array of substantially flat mirrors arranged to reflect sunlight to a target, wherein the target is located at a predetermined distance from the array of mirrors; and at least one solar tracking mechanism coupled to the array of mirrors, wherein the solar tracking mechanism is designed to adjust the position of the array of mirrors in relation to the location of the sun such that solar rays are continually directed to the target for at least a portion of the traverse of the sun across the sky.

In other embodiments, a solar energy collection and conversion system is provided. The system comprises: a plurality of substantially flat mirrors arranged near one another; a target comprising a photovoltaic cell located at a predetermined distance from at least one of the plurality of substantially flat mirrors, wherein each of the plurality of substantially flat mirrors is positioned to direct solar rays to the target; a thermally conductive substrate coupled to the photovoltaic cell; a fluid pipe coupled to the thermally conductive substrate, the fluid pipe containing a fluid that absorbs heat transferred to the fluid pipe by the thermally conductive substrate; and at least one solar tracking mechanism coupled to each of the plurality of substantially flat mirrors, wherein the solar tracking mechanism is designed to adjust the position of each of the plurality of substantially flat mirrors in relation to the location of the sun such that solar rays are continually directed to the target for at least a portion of the traverse of the sun across the sky.

A method of collecting solar energy is also provided. The method comprises: arranging a plurality of substantially flat mirrors near one another; positioning a target at a predetermined distance from at least one of the plurality of substantially flat mirrors; positioning each of the plurality of substantially flat mirrors to direct solar rays to the target; adjusting the position of each of the plurality of substantially flat mirrors using at least one solar tracking mechanism, wherein the at least one solar tracking mechanism adjusts the position of each of the plurality of substantially flat mirrors in relation to the location of the sun; and directing solar rays to the target for at least a portion of the traverse of the sun across the sky.

A method for solar energy collection and conversion is additionally provided. The method comprises arranging a plurality of substantially flat mirrors near one another; positioning a target at a predetermined distance from at least one of the plurality of substantially flat mirrors; positioning the plurality of substantially flat mirrors to direct solar rays to the target; adjusting the position of the plurality of substantially flat mirrors using at least one solar tracking mechanism, wherein the at least one solar tracking mechanism adjusts the position of the plurality of substantially flat mirrors in relation to the location of the sun; directing solar rays to the target for at least a portion of the traverse of the sun across the sky; coupling a thermally conductive substrate to the target; and coupling a fluid pipe to the thermally conductive substrate, the fluid pipe containing a fluid that absorbs heat transferred to the fluid pipe by the thermally conductive substrate.

In additional embodiments, a support plate for mounting a substantially flat mirror is provided. The support plate comprises a flat flange portion to which the mirror is coupled with brackets mounted on tabs protruding from the support plate; a tubular projection that extends from the flange portion in the direction opposite the mirror; a ball-and-stem component coupled to the tubular projection; and a mounting element to which the ball-and-stem component is mounted, wherein the mounting element comprises a chamber that accommodates the ball-and-stem component, allowing movement of the ball-and-stem component therein.

Other objects, features, and advantages of the illustrative embodiments will become apparent with reference to the drawings and detailed description that follow.

### BRIEF DESCRIPTION OF THE DRAWINGS

FIG. 1 is a perspective view of one embodiment of the solar collector described herein.

FIG. 2 is a perspective view of a support structure for a mirror as provided in one embodiment described herein, as seen through the mirror.

FIG. 3 is a perspective view of the non-mirror side of a support structure for a mirror as provided in one embodiment described herein.

FIG. 4 is a perspective view of a ball-and-stem component as provided in one embodiment described herein.

FIG. 5 is a side cross-sectional view of a mirror support structure connected to a mount via a ball joint as provided in one embodiment described herein.

FIG. 6 is a perspective view of a mounting element as provided in one embodiment described herein.

FIG. 7 is a perspective of the underside of a portion of a mirror array as provided in one embodiment described herein.

FIG. 8 is a perspective view of a portion of a supporting structure for a solar collector as provided in one embodiment described herein.

FIG. 9 is a perspective view of a portion of a support structure and movement mechanism for a solar collector as provided in one embodiment described herein.

FIG. 10 is a perspective view of a portion of a support structure for a solar collector as provided in one embodiment described herein.

FIG. 11 is a perspective view of a light tube and associated lenses and photovoltaic cell as provided in one embodiment described herein.

FIG. 12 is a perspective view of a section of a fluid pipe and associated steam handling equipment as provided in one embodiment described herein.

FIG. 13 is a perspective view of one embodiment of the solar collector described herein.

### DETAILED DESCRIPTION

As required, a detailed embodiment of the present application is disclosed herein; however, it is to be understood that the disclosed embodiment is merely exemplary of the principles of the application, which may be embodied in various forms. Therefore, specific structural and functional details disclosed herein are not to be interpreted as limiting, but merely as a basis for the claims and as a representative basis for teaching one skilled in the art to variously employ the present application in virtually any appropriately detailed structure.

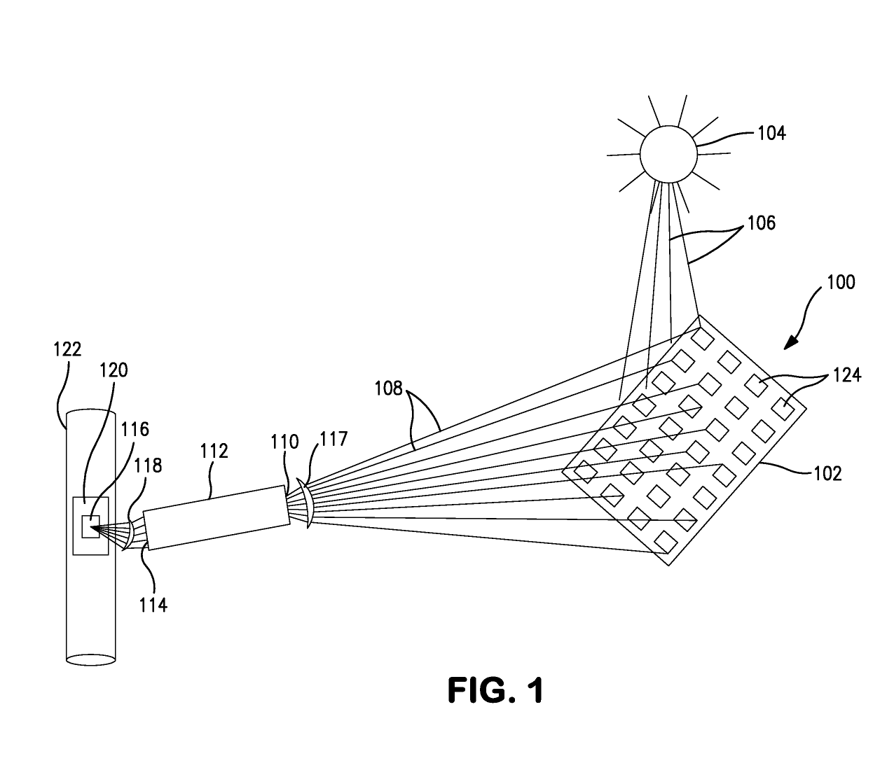

One embodiment, in a general sense, is shown in FIG. 1, is a solar collector that comprises at least one mirror array 100, mounted to a support structure 102 that moves in correspondence to the sun 104 as it passes through the sky. The mirrors in the array may have any shape including but not limited to circular, square, rectangular, triangular, oval, cruciate, elliptical or polygonal. There may be any number of mirrors in the array. In some embodiments, there are more than 10 mirrors. In other embodiments, there are more than 15 mirrors. In additional embodiments, there are more than 20 mirrors. In further embodiments, there are more than 30, 40, 50, 60, 70, 80, 90 or 100 mirrors. The mirror array may be positioned such that, as the sun's rays 106 is reflected off each mirror, the reflected light 108 converges onto a common target located some distance away from the array of mirrors and support structure. As used herein, the target is the device that receives the light and converts at least a portion of it into a different form, e.g., heat or electricity. Before impinging on the target, the light reflecting off of the array can be redirected by, e.g., a mirror, lens or light pipe. As illustrated in FIG. 1, the light reflected off of the array enters the opening 110 of a light pipe 112. As used herein, a “light pipe” is a tube having a reflective interior surface along which at least a portion of the light that enters the opening passes through the pipe and exits out of the end of the tube.

A lens 117 is optionally positioned before the opening 110 of the light pipe to focus the light into the light pipe. The end 114 of the light pipe 112, from which the light exits, is positioned in close proximity to a concentrator photovoltaic (CPV) panel 116. Optionally, a lens 118 focuses the light exiting the light pipe 112 onto the CPV panel 116

While the illustrated embodiments utilize a CPV panel as the target, these embodiments are not narrowly limited to any particular target. Nonlimiting examples of other targets are other photovoltaic cells, heat engines, reservoirs of water or molten salt, thermal energy storage devices and thermal energy conversion device, as they are known in the art.

While it is possible, as further described below, to utilize a series of collimating lenses and mirrors to produce a beam of concentrated light and direct it towards a target such as a CPV panel 116, rather than using a light pipe 112, it shall be understood that there are several advantages of using a light pipe 112 to transmit the concentrated light 108 from the mirror array to the CPV panel. These advantages include: (a) that light transmitted through a light pipe 112 is typically diffused into a constant or uniform intensity as it traverses the light pipe 112, thereby providing an approximate uniform intensity of light across the face of the CPV panel 116, thus settling out any differences in intensity that could reduce the energy conversion efficiency of the CPV panel 116; (b) the diameter of the light pipe 112 can be narrowed from the opening 110 to the end 114, thereby serving to further concentrate the intensity of the light, and (c) the light pipe 112 may include bends and angles that permit the location of the CPV panel 116 to be largely independent of the placement of the mirror array. It shall further be understood that the merging of two light pipes 112 may also be advantageous, thus further increasing the intensity of the light deposited on the CPV panel 116

While the CPV panel is mounted to a thermally conductive substrate (for example, a copper plate 120) that is built into, onto or coupled to a fluid pipe 122, through which fluid is circulated, and the CPV panel 116 is kept in contact with the conductive substrate to draw off the waste heat produced by the light that is not converted into electricity by the CPV panel.

This fluid pipe, in certain embodiments, contains flowing salt water (for example from the ocean, or from a salt water aquifer). In such embodiments, it shall be understood that one of the purposes of having the fluid pipe is to boil the water in the pipe and thus produce desalinated water by capturing the steam and re-condensing it in a separate reservoir. It shall be further appreciated that additional energy may be extractable from the steam produced through this CPV waste energy capture by the fluid. It shall be appreciated that, in order to maximize the heating of the water flowing through the fluid pipe 122, it would be desirable to have a plurality of mirror arrays 102 and light pipes 112 all feeding light, and CPV panels 116 feeding heat energy into the fluid pipe 122. Additionally, the fluid pipe 122 itself may be constructed of an energy absorbing material so that additional light energy may be directed onto the pipe to enhance the heating of the water.

More specifically, with respect to the aspects inherent in the embodiment introduced above, a solar collector is provided. In one embodiment, the solar collector includes a plurality of flat mirrors. Flat mirrors are advantageous over curved or parabolic mirrors in materials and manufacturing costs. In some aspects, the flat mirrors are relatively small and square shaped, in some embodiments less than 24 inches per side.

Each of the flat mirrors 124 is aimed so as to direct solar rays at a common target. The target is located a set distance from the mirrors. The solar collector collects solar rays via the flat mirrors and directs the solar rays from each of the flat mirrors onto the target. In this way, the solar rays received by the target are of greater intensity than the direct sunlight that would reach the target independent of the solar collector. In some embodiments, the flat mirrors and the target are arranged such that the distance between the mirrors and the target is at least about 100 times the width or diameter of each of the mirrors or at least one of the mirrors, if the mirrors are not uniformly sized. Arranging the mirrors and target at a distance of about 100 times the width or diameter of the mirrors, or greater, provides that the reflected image is almost entirely direct sunlight, with little or no wasted background “blue sky.” In these embodiments, the target may be physically located anywhere with respect to the mirrors, provided the distance from the mirrors remains about 100 times, or greater, the width or diameter of each mirror. In some aspects, each mirror is identical in size and shape. In some embodiments, the target is disposed at a position away from the mirrors. In other embodiments, the target is disposed between the mirrors and the sun.

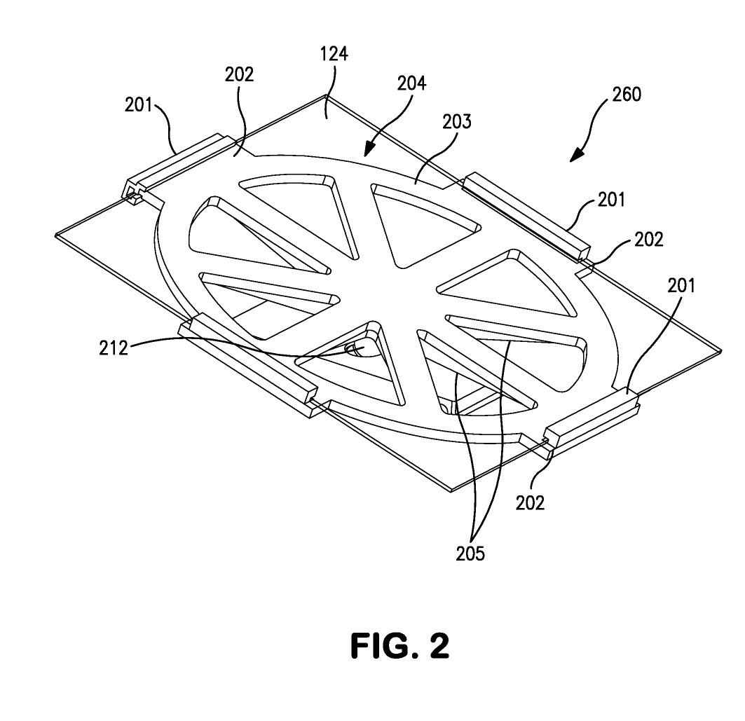

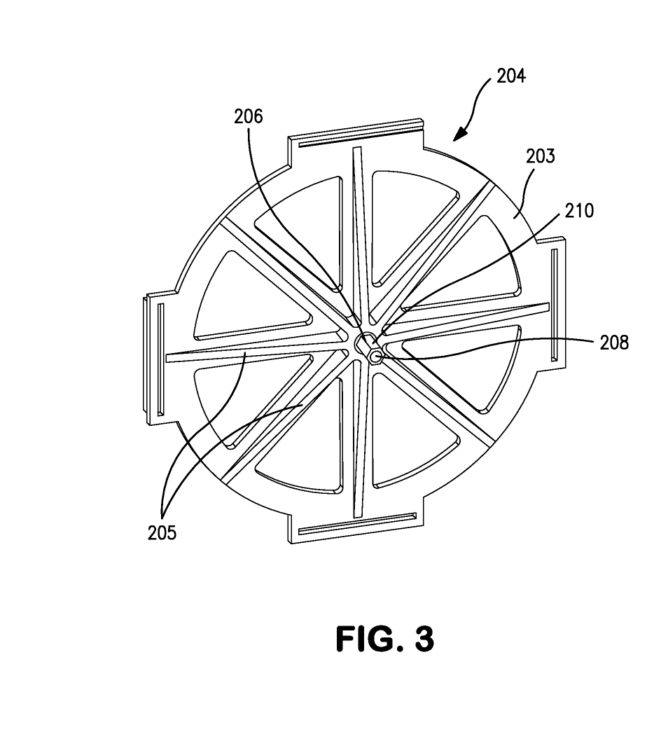

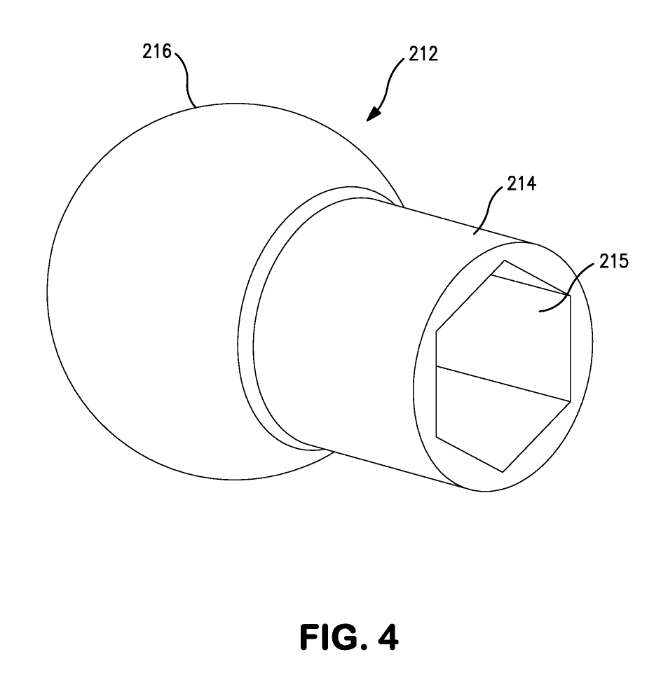

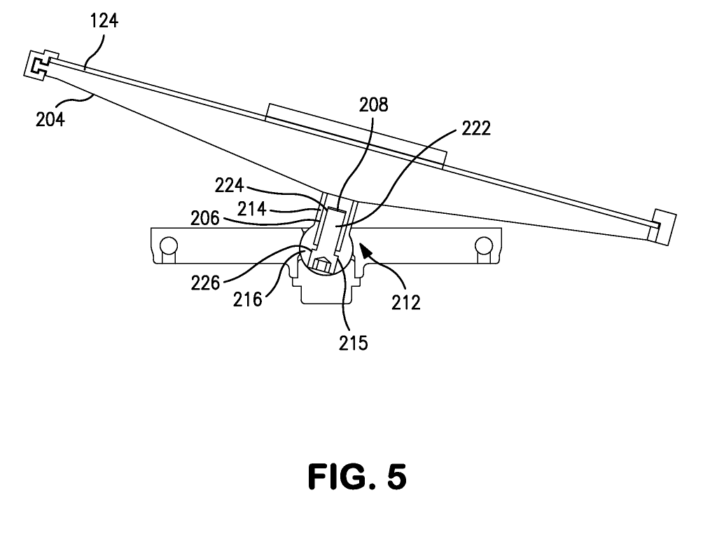

With respect to a specific embodiment of the mirror array 100, a mounting assembly 260 for an individual mirror 124 is shown in FIG. 2, each mirror 124 is attached to a support plate 204 with brackets 201 mounted on support plate tabs 202 protruding from the support plate 204. The support plate 204 also has a flat flange portion 203 to which the non-reflective back portion of the mirror is adhered or coupled. As shown in FIG. 3, the support plate 204 further includes a tubular projection 206 that extends posteriorly from the flange portion 203 (i.e., in the direction opposite the mirror surface), approximately perpendicular to the mirror surface. As shown in FIGS. 2 and 3, a series of diagonal supports 205 may also be incorporated to enhance the rigidity of the structure. The tubular projection 206 includes an interior hole 208 that is threaded, and an exterior surface 210 that is hexagonal. As shown in FIGS. 2 and 4, the support plate 204 is coupled to a ball-and-stem component 212, including a stem portion 214 having a hexagonally shaped interior cavity 215, and a ball-shaped portion 216. The tubular projection 206 is designed such that the exterior surface 210 seats within the interior cavity 215 of the hollow stem portion 214 of ball-and-stem component 212. As shown in FIG. 5, the interior cavity 215 extends through the stem portion 214 into the ball-shaped portion 216, and is collinear with the interior hole 208 of tubular projection 206. A threaded screw 222, having a threaded shaft portion 224 and a rounded head portion 226, is provided that is shaped to be inserted along the interior cavity 215 in the ball-and-stem component 212 and engage with the threaded hole 208, thereby locking the support plate 204 with the ball-and-stem component 212.

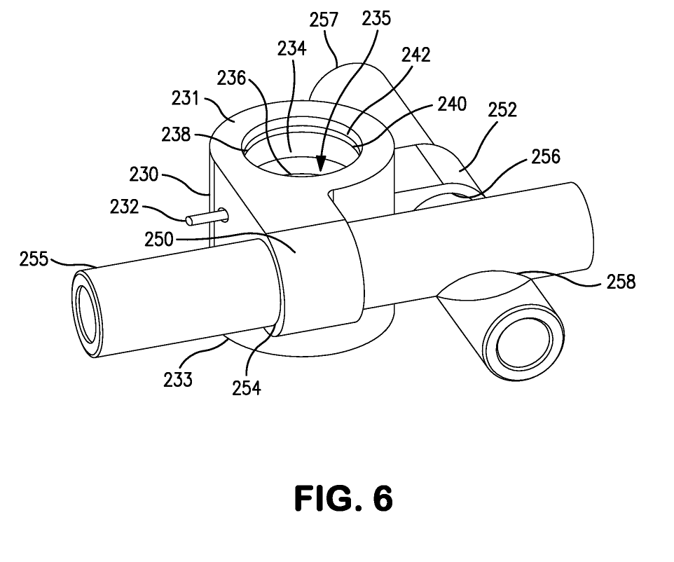

As further shown in FIG. 6, the present embodiment further comprises a mounting element 230 and set screw 232. The mounting element 230 has an upper surface 231, a lower surface 233, and a central axial hole 234, with a threading disposed on the interior surface 236 at the lower end 235 of the axial hole 234, and a chamber 238 at the upper end thereof. The chamber 238 includes a sufficient volume to accommodate the ball-shaped portion 216. It shall be understood that nothing herein requires that the lower end 235 of the axial hole 233 and the chamber 238 be separated from one another, and it can be readily seen by one skilled in the art how hole 235 and chamber 238 may either be distinct or overlapping. The chamber 238 further comprises an upper region 240 that has a diameter that is tapered (either linearly or curved), or alternatively includes a separate engageable means (for example, a snap ring or other such device) that mates with the upper region 240 such that when it is engaged the ball-shaped portion 216 cannot pass through the upper end 242 of the axial hole 234.

Set screw 232 is positionable in the lower end of the axial hole 234, and advanceable along the threading thereof, into contact with the ball-shaped portion 216. Prior to tightening of the set screw 232, the dimensions of the upper end 240 of the hole 234 are such that the ball-shaped portion may rotate in any direction within the chamber 238, thus permitting the mirror 124 to be moved through a multiplicity of angles. Tightening of the set screw 232 against the ball-shaped portion 216 forces the ball-shaped portion 216 into the portion or aspect of the upper region 240 of the hole 234 that has the narrower diameter than the rest of the hole 234, thus compression-locking the ball-shaped portion within the chamber 238, and thereby locking the support plate 202 and mirror 204 in a fixed orientation. It shall be understood that the diameter of the ball-shaped portion 216 must be larger than the narrow diameter of the upper portion or aspect of the upper region 240.

The mounting element 230 further comprises a pair of rod-receiving protuberances 250 and 252 that have holes 254 and 256, respectively, extending therethrough. In this embodiment, the holes 254 and 256 are oriented perpendicular to one another, and mutually perpendicular to the axial hole 234. While hole 254 is disposed such that a cylindrical rod having a diameter approximately equal to that of the hole 254 extending therethrough would be closer to the upper surface 231 than a similar rod extending through hole 256, the relative orientations of the holes 254 and 256 are such that were two such rods to simultaneously extend through holes 254 and 256, the rods would interfere with one another.

Support rods 255 and 257 are provided, with rod 255 including a notch 258 that permits rod 257 to be simultaneously extended through hole 256 when rod 255 is inserted through hole 254, provided that notch 258 is disposed in a position co-linear with the axis of the rod 257 and the axis of the through hole 256. It shall be understood that either or both rods could include the notches to prevent interference, but so long as one rod does include the notches, they further provide a means for holding the assembly in a locked configuration when assembled. As illustrated, rod 257 also includes a notch 259 that aligns with the notch 258 on rod 255.

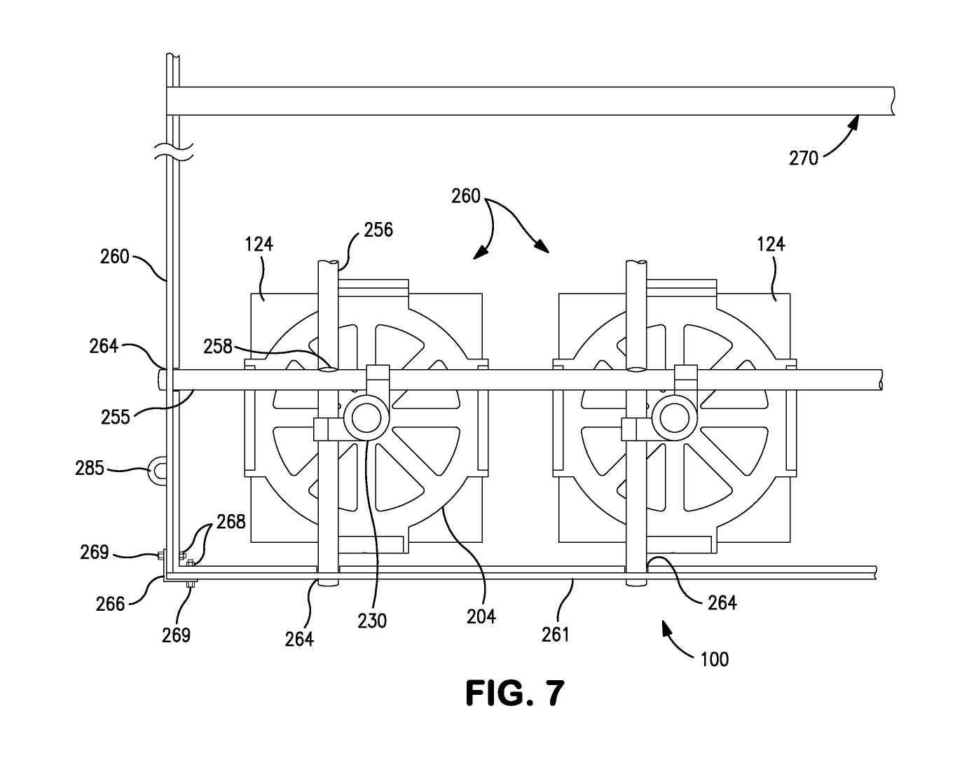

Referring now to FIG. 7, a corner portion of a mirror array 100 is shown from below, having mirrors 124 mounted to corresponding mounting assemblies 260, and including support plates 204, mounting elements 230, and rods 255 and 256. A square array 100 including a plurality of mirrors is shown, with a series of rods 255 extending in parallel in a plane along one direction, and rods 256 (with notches 258) extending in a plane along the perpendicular direction. The mounting elements 230 are equally spaced close to each of the intersections of rods 255 and 256. The ends of rods 255 and 257 terminate at C-bars 260, 261, to which the rods 255 and 256 are attached by means of nuts engaging threaded ends of the rods 255 and 256 as they extend through holes 264 in the C-bars 260, 261.

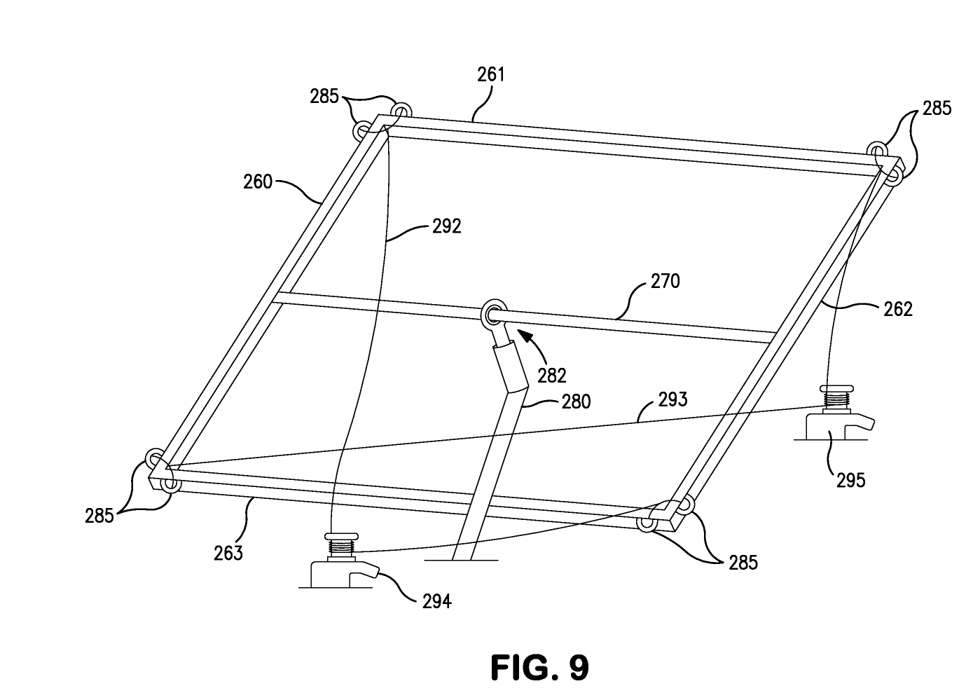

C-bars 260, 261 are disposed in a square beneath the mirrors 124 forming the perimeter of the mirror array 100 (each C-bar forming one side of the square—see also FIG. 9), and are coupled by means of angle irons 266 and nuts and bolts 268 and 269, respectively. Coupled to the array at the mid-point of C-bars 261 and 263 is a support spar 270 that extends across the array beneath the mirror mountings (the underside of the mirror array).

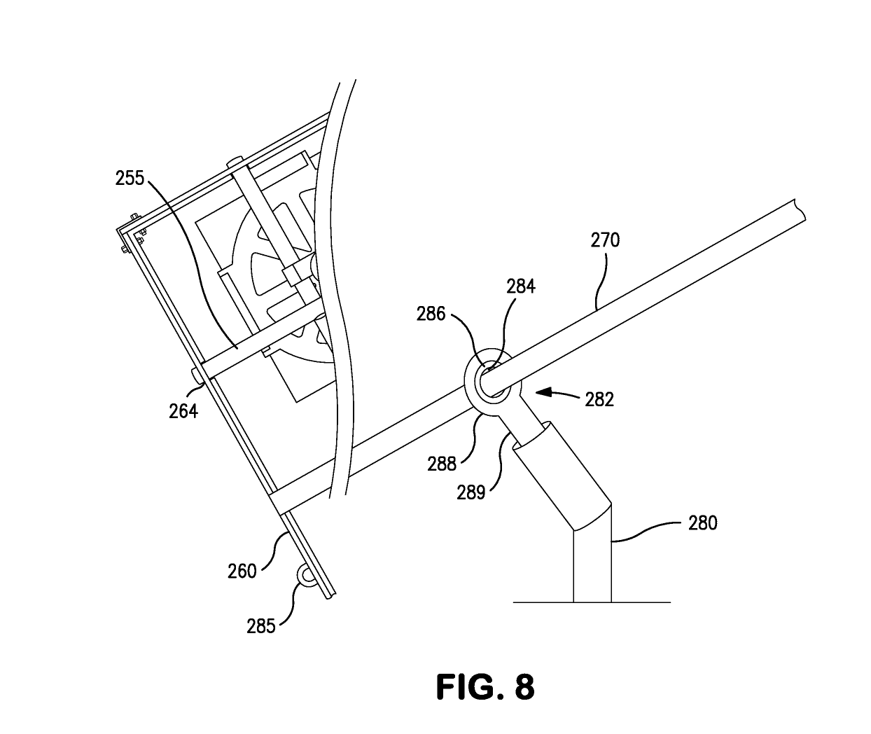

With reference now to FIG. 8, the support spar 270 is coupled to a solid support post 280 via a flexible mounting, which in the present embodiment is a high misalignment rod end 282. The rod end 282 has a bearing element 286 and a housing 288 having a shaft portion 289. The shaft portion 289 is a threaded bolt which can be threaded into the top of the support post 280. An example of a suitable rod end is the HXAM-12™ High Misalignment Series Male Rod End manufactured by the Aurora Bearing Company of Aurora, Ill. More specifically, the rod end 282 is mounted at a 45° angle to the top of the support post 280, and is aligned so that the axis of the hole 284 therethrough is, in its neutral position, orthogonal to the terrestrial projection of the sun across the sky (i.e., the line connecting the points on the horizon of the sunrise and sunset), but offset by 45 degrees to the surface of the Earth. The mirror array in the neutral position and also angled at 45 degrees to the surface of the Earth permits all of the noon direct sunlight incident on the mirrors to be easily directed toward a common first target that is at the same height off the ground as the center of the array. As is discussed more fully below, this further permits the sun to be tracked across the sky, and all of the direct sunlight to be directed constantly toward the exact same stationary common first target.

More particularly, again, with respect to the mating of the support spar 270 to the rod end 282, this orientation permits the support spar 270 to rotate within the central bearing 286 of the rod end 282, around the axis of the hole 284 to follow the sun across the sky each day. The high misalignment of the exemplified central bearing 286 within the housing 288 permits the support spar 270 (and the mirror array) to pivot in the orthogonal direction as well, thus permitting the array to accommodate the change in the inclination of the sun in the sky throughout the year. To be clear, the sun, the mirrors of the array, and the target form three points that serve as the vertices of a triangle. By aligning the array as described above, and specifically mounting the array to the support post 280 with a high misalignment rod end 282, the array can rotate on the support spar 270 toward the horizon where the sun rises in the morning, slowly pivot to track the sun through the day, and ultimately back toward the horizon where the sun sets in the evening (even adjusting for the changes in these specific locations throughout the year), all the while reflecting the incident sunlight onto the mouth of the light pipe 290.

As illustrated in FIG. 9, the C-bars 260-263 further include a plurality of rope- and/or wire-securing structures 285 disposed at the ends thereof (illustrated in FIGS. 7-9 as simple loops through which the ropes and/or wires can be inserted and secured). Two wires 292 and 293 are each attached to respective pairs of diagonally opposing corners of the C-bar frame (the square formed by the 4 C-bars). These wires 292 and 293 are each passed around motorized capstans 294 and 295 (one wire per capstan). The motorized capstans 294 and 295 can, when controlled by a standard heliostat program, cause the mirror array to pivot around the rod end 282 to maintain the proper position relative to the sun and the light pipe 290.

It shall be understood by one of ordinary skill in the art that many mechanisms exist for rotating the array through the various angles necessary to track the sun, and that the system provided above may be substituted with any other mechanism without deviating from the broad spirit and scope of the instant solar collectors. Alternative embodiments for these mechanisms can include the use of worm gears or CV joints. It should be noted, however, that any system or mechanism selected for this purpose is preferably simple and inexpensive in order to maintain the economic advantages associated with these solar collectors.

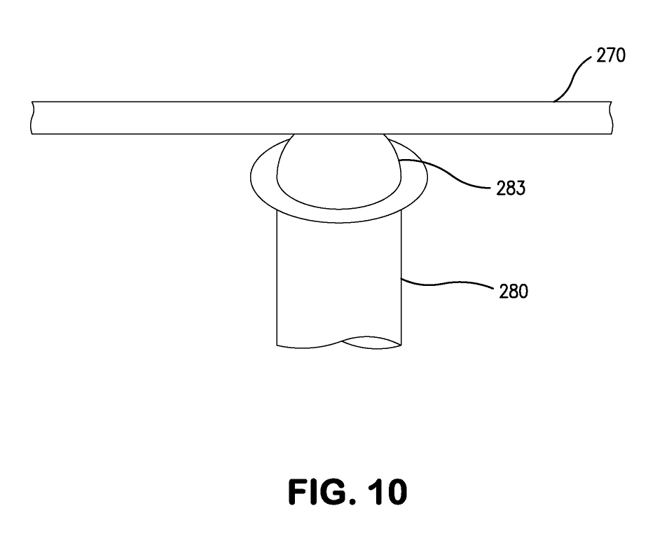

In one alternate embodiment, as shown in FIG. 10, the support spar 270 is joined to the support post 280 with a ball joint 283, allowing rotation, e.g., as controlled by the wires 292 and 293 wound around the motorized capstans 294 and 295.

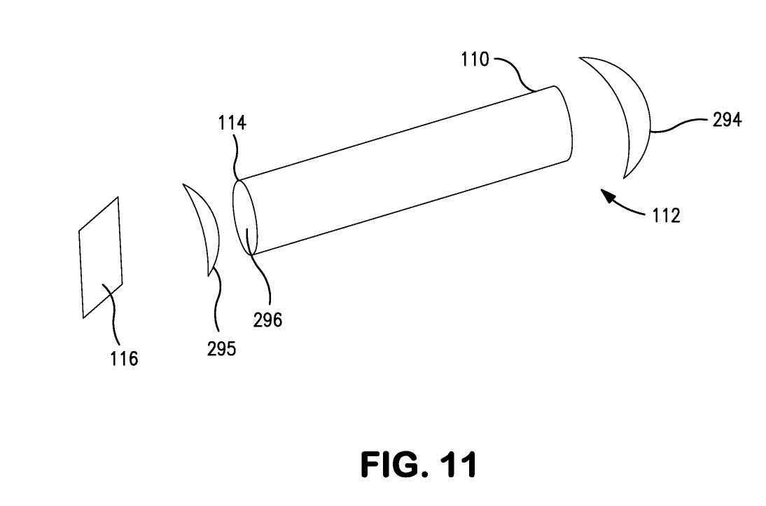

Referring to FIG. 11, the light pipe 112, is an elongate tube having an opening 110, an end 114, and an interior surface 296. The interior surface 296 of the pipe is coated with a highly reflective material such that light introduced into the opening 110 is reflected along the interior of the pipe 112 and exits through the end 114. It shall be understood that typical reflective materials are not completely reflective (i.e., do not reflect 100% of the light incident upon the surface), but rather impart some slight loss of intensity with each reflection. The factors that determine how much of a loss of total light is experienced from the first end and the second end of the light pipe include: (a) the intrinsic optical properties of the reflective surface 296; (b) the degree to which the interior reflective surface 296 is polished; (c) the wavelength of the light incident on the reflective surface 296; (d) the average angle of incidence of the photons against the reflective surface 296; and (e) the average number of times a photon is reflected as it travels along the tube. With respect to the latter of these factors, an entry lens 294 may be positioned adjacent to the opening 110 of the light pipe 112. The entry lens 294 is utilized to alter the average angle of entrance of the photons into the pipe so that the average angle of incidence of the photons against the interior surface is reduced (smaller angles of incidence reduces the reflectance losses) and simultaneously the total number of reflections per unit of pipe length is reduced. The entry lens 294 can also direct portions of the light reflected from the mirror array 100 that would otherwise not enter the light pipe, into the light pipe 112.

Similarly, an exit lens 295 may be mounted at the end 114 of the light pipe 112 to focusing the light exiting the light pipe 112 onto the desired area (for example, a CPV panel 116). One of the advantages of a light pipe is that it permits the light to be carried away from the solar collection source to a remote location where the light energy may be used in a more controlled fashion. Another advantage of the light pipe in the present embodiment is that the process of traversing the pipe, and the corresponding series of reflections that occur along its extent, tends to even out the intensity of the light. This serves to mediate one challenge associated with using solar panels, which is that the amount of electricity generated by a given panel, or even a given array of panels in series, is proportional to the minimum amount of light incident on a given cell within the panel or series. An even intensity of light incident on the CPV ensures the maximum amount of electricity output.

A further advantage of using a light pipe, as suggested above, is that a smooth (i.e., small continuous) reduction in the diameter of the pipe from the opening 110 to the end 114 can be employed to concentrate the light exiting the end 114. Similarly, two light pipes may be merged at a sufficiently small angle to concentrate the light passing through the terminal end.

It shall be understood that neither the lenses 294 or 295, nor a decreasing diameter of a single light pipe, nor merged light pipes is required to appreciate the present embodiments. These features, if employed, are simply enhancements of specific embodiments of the aspect of the underlying embodiments that direct the light energy from the mirror array to energy conversion.

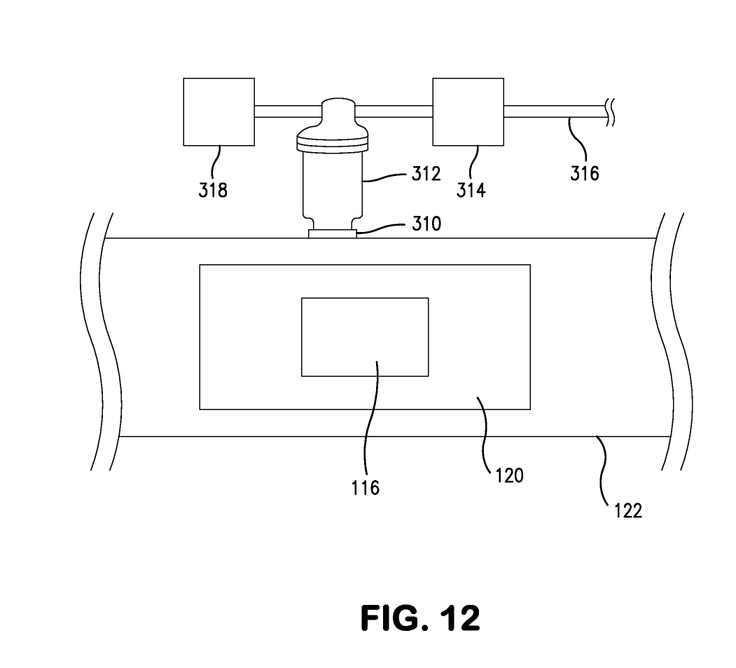

Referring to FIG. 12, an elongate section of the fluid-carrying pipe 122 of an embodiment of the solar collector is shown. In an alternative embodiment, a reservoir can be substituted for the fluid-carrying pipe 122. In the illustrated embodiment, a CPV panel 116 is mounted to a copper substrate 120. CPV panel 116 can include an integral miniature transformer (not shown) that converts the DC power generated by the panel into an alternating current that can be directly utilized by motorized elements of the solar collector (e.g., the motorized capstans 294 and 295 illustrated in FIG. 9) and/or transmitted into the local electric power grid (not shown). Alternatively, each panel may be connected to another CPV panel in a series, and the resulting DC power transmitted to motorized elements of the solar collector or to a large transformer that converts the power into alternating current for transmission into the local electric power grid.

The copper substrate 120 is mounted to, and serves as a portion of, the sidewall of the fluid pipe 122. By passing a fluid with a sufficiently high thermal conductivity (such as water) past the copper substrate 304 on the inside of the pipe, waste heat generated during the conversion of the concentrated sunlight directed at the CPV panel 116 can be absorbed by the fluid, thus maintaining a steady state temperature within the CPV panel 116 that is within its safe and efficient operating range, and heating the fluid passing through the pipe.

In some embodiments, the fluid in the pipe be water, and in certain embodiments, salt water. Water has a very high latent heat of evaporation (2260 Joules per gram), which means that as its temperature reaches its boiling point, the amount of energy necessary to induce the phase change from liquid to vapor is significantly greater than that for other common fluids like alcohol (855 joules per gram). As a result of this physical property, water can serve as a great absorber of heat at a near constant temperature. As the water continues to absorb energy after reaching 100 degrees Celsius, a portion of the liquid will be converted to steam. Impurities in the water, such as salt, typically do not evaporate with the water during this phase conversion, thus boiling is a traditional means for purifying water of salts. By the same measure, temperatures at which water boils are far above those tolerable by most pathogens, and thus boiling is also a well accepted means of substantially eliminating pathogens.

More specifically, with respect to the fluid pipe of these embodiments, the upper surface of the pipe 122 includes a port 310 that includes a steam trap 312 (such as the 2000 Series Inverted Bucket Steam Trap available through Armstrong International, Inc., www.armstronginternational.com). The steam output of the steam trap 312 can be easily recovered with a condenser 314 to provide fresh water, which can be transported separately through a secondary fluid pipe 316. Alternatively, if additional energy recovery is desired, the output of the steam trap 312 can be directed to a secondary power generation stage 318.

The secondary power generation stage 318 can comprise any system known or later discovered for converting steam to energy. In some embodiments, this stage comprises a steam heating chamber, a turbine, a generator and a condenser. The steam heating chamber optionally includes a burner to add more heat to the steam, or it may be positioned to receive additional concentrated solar energy onto its surface to heat the steam contents of the chamber.

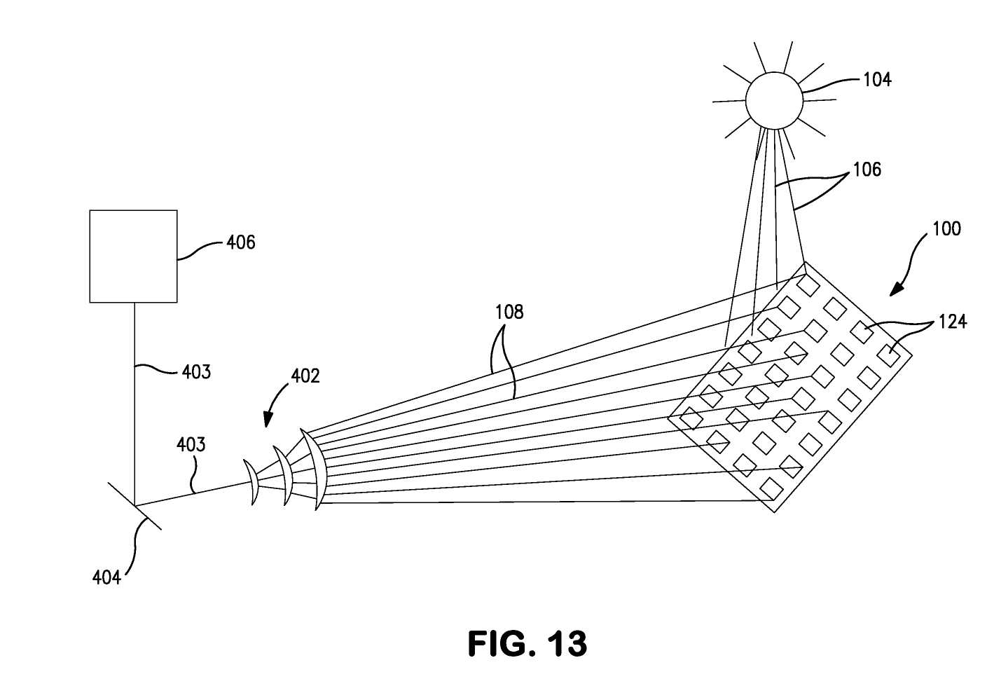

In an alternative embodiment, illustrated in FIG. 13, the solar collection array 100 is constructed in the same manner as in the prior embodiment, but the first target in this embodiment is a series of lenses (e.g., a Fresnel lens) 402 that collimate the reflected solar radiation 108 into a beam 403. This beam 403 is then directed by at least one mirror 404 (in the simplest configuration a single mirror) onto the second target 406. The second target 406 in this embodiment is the heating stage of a typical steam driven power plant (wherein the heat source is the beam 403 (or a plurality of beams) of solar energy.

It shall be understood that many alternative systems may be contemplated that utilize the concentrated solar energy contained either in the light pipe of the first embodiment, or the at least one beam of the second embodiment, and that one of ordinary skill in the art may seek to exchange the energy conversion systems of these embodiments without deviating from the broad scope of the present invention.

In view of the above, it will be seen that the several advantages of the invention are achieved and other advantages attained.

As various changes could be made in the above methods and compositions without departing from the scope of the invention, it is intended that all matter contained in the above description and shown in the accompanying drawings shall be interpreted as illustrative and not in a limiting sense.

1. A solar collector comprising:
an array of substantially flat mirrors arranged to reflect sunlight to a target, wherein the target is located at a predetermined distance from the array of mirrors; and
at least one solar tracking mechanism coupled to the array of mirrors, wherein the solar tracking mechanism is designed to adjust the position of the array of mirrors in relation to the location of the sun such that solar rays are continually directed to the target for at least a portion of the traverse of the sun across the sky.

2. The solar collector of claim 1, further comprising at least one lens having a design suitable to collimate the solar rays reflected from the array of mirrors, wherein the lens is positioned to intercept said solar rays.

3. The solar collector of claim 2, wherein the lens is a Fresnel lens.

4. The solar collector of claim 2, further comprising a targeting mirror positioned to direct the solar rays from the at least one lens to the target.

5. The solar collector of claim 1, further comprising a targeting mirror positioned to direct the solar rays from the array of mirrors to the target.

6. The solar collector of claim 1, further comprising a light pipe having an opening and an end, wherein the opening of the light pipe is positioned to substantially intercept the solar rays from the array of mirrors and substantially direct said solar rays out of the end of the light pipe to the target.

7. The solar collector of claim 6, wherein the light pipe is narrower at the end than the opening such that the solar rays directed out of the light pipe is concentrated by passing through the light pipe.

8. The solar collector of claim 1, wherein the target comprises a heat engine, a reservoir of water or molten salt, a photovoltaic cell, a thermal energy storage device and/or a thermal energy conversion device.

9. The solar collector of claim 1, wherein the target comprises a photovoltaic cell.

10. The solar collector of claim 9, wherein the photovoltaic cell is a high efficiency photovoltaic cell or a concentrator photovoltaic cell.

11. The solar collector of claim 1, wherein the target comprises a thermally conductive substrate on a fluid pipe or reservoir.

12. The solar collector of claim 1, wherein the target comprises a photovoltaic cell mounted on a thermally conductive substrate on a fluid pipe or reservoir.

13. The solar collector of claim 12, wherein the fluid pipe or reservoir comprises water.

14. The solar collector of claim 13, wherein the water is salt water.

15. The solar collector of claim 13, wherein the fluid pipe or reservoir further comprises a steam trap.

16. The solar collector of claim 13, wherein the water in the fluid pipe or reservoir can produce steam when the target is exposed to light from the array.

17. The solar collector of claim 1, The solar collector of claim 1, wherein the plurality of substantially flat mirrors are arranged adjacent to one another in a pattern.

18. The solar collector of claim 17, wherein the pattern is a Fresnel pattern.

19. A solar energy collection and conversion system, comprising:
a plurality of substantially flat mirrors arranged near one another;
a target comprising a photovoltaic cell located at a predetermined distance from at least one of the plurality of substantially flat mirrors, wherein each of the plurality of substantially flat mirrors is positioned to direct solar rays to the target;
a thermally conductive substrate coupled to the photovoltaic cell;
a fluid pipe coupled to the thermally conductive substrate, the fluid pipe containing a fluid that absorbs heat transferred to the fluid pipe by the thermally conductive substrate; and
at least one solar tracking mechanism coupled to each of the plurality of substantially flat mirrors, wherein the solar tracking mechanism is designed to adjust the position of each of the plurality of substantially flat mirrors in relation to the location of the sun such that solar rays are continually directed to the target for at least a portion of the traverse of the sun across the sky.

20. A method of collecting solar energy, the method comprising:
arranging a plurality of substantially flat mirrors near one another;
positioning a target at a predetermined distance from at least one of the plurality of substantially flat mirrors;
positioning each of the plurality of substantially flat mirrors to direct solar rays to the target;
adjusting the position of each of the plurality of substantially flat mirrors using at least one solar tracking mechanism, wherein the at least one solar tracking mechanism adjusts the position of each of the plurality of substantially flat mirrors in relation to the location of the sun; and
directing solar rays to the target for at least a portion of the traverse of the sun across the sky.
